(19) United States
(12) Patent Application Publication
(10) Pub. No.: US 2025/0212634 A1
(43) Pub. Date: Jun. 26, 2025

(54) DISPLAY DEVICE

(71) Applicant: LG Display Co., Ltd., Seoul (KR)

(72) Inventors: Sungbin Shim, Yangsan-si (KR); Dahye Kwon, Seoul (KR); SangWon Lee, Paju-si (KR)

(73) Assignee: LG Display Co., Ltd., Seoul (KR)

(21) Appl. No.: 18/930,914

(22) Filed: Oct. 29, 2024

(30) Foreign Application Priority Data
Dec. 20, 2023 (KR) 10-2023-0161539

(51) Int. Cl. H10K 59/131

(52) U.S. Cl. CPC H10K 59/131

(57) ABSTRACT

A display device may include a substrate, a transistor on the substrate, a planarization layer on the transistor, a plurality of light-emitting elements on the planarization layer and in a same subpixel, and a connection line configured to adjoin the transistor and the plurality of light-emitting elements. The connection line may cover an end of an anode of each of the plurality of light-emitting elements and may be made of transparent conductive oxide.

### CROSS-REFERENCE TO RELATED APPLICATION

This application claims the priority of Korean Patent Application No. 10-2023-0161539, filed on Nov. 20, 2023, in the Korean Intellectual Property Office, the disclosure of which is incorporated herein by reference.

### BACKGROUND

### Field

The present specification relates to a display device and, more particularly, to a display device capable of minimizing a deterioration in reliability caused by repairing a defective subpixel.

### Description of the Related Art

As display devices used for a monitor of a computer, a TV set, a mobile phone, and the like, there are an organic light-emitting display (OLED) device configured to autonomously emit, and a liquid crystal display (LCD) device that requires a separate light source.

The range of application of the display devices is diversified from the monitor of the computer and the TV set to personal mobile devices, and studies are being conducted on the display devices having wide display areas and having reduced volumes and weights.

Meanwhile, after the process of manufacturing the display device, an illumination inspection process may be performed on the display device to detect a defective subpixel having a dark spot defect or a bright spot defect. When the defective subpixel is detected, a repair process of separating an anode of the defective subpixel from a pixel circuit by using a laser may be performed.

### SUMMARY

An object to be achieved by the present disclosure is to provide a high-efficiency, low-power display device capable of minimizing a deterioration in reliability of a peripheral portion caused by physical deformation of a connection line irradiated with laser beams during a repair process.

Another object to be achieved by the present disclosure is to provide a display device in which a plurality of light-emitting elements and transistors are easily separated electrically by using a portion of a connection line, which has a small thickness, as a repair point.

Objects of the present disclosure are not limited to the above-mentioned objects, and other objects, which are not mentioned above, can be clearly understood by those skilled in the art from the following descriptions.

To achieve these objects and other advantages of the present disclosure, as embodied and broadly described herein, a display device according to an example embodiment of the present disclosure may include a substrate, a transistor on the substrate, a planarization layer on the transistor, a plurality of light-emitting elements on the planarization layer and in a same subpixel, and a connection line configured to adjoin the transistor and the plurality of light-emitting elements. The connection line may cover an end of an anode of each of the plurality of light-emitting elements and may be made of transparent conductive oxide.

In another aspect of the present disclosure, a display device according to an example embodiment of the present disclosure may include a substrate on which a plurality of subpixels are disposed; a transistor disposed in each of the plurality of subpixels on the substrate; a first light-emitting element and a second light-emitting element disposed in one subpixel, among the plurality of subpixels, and electrically connected to the same transistor; and a connection line configured to electrically connect the transistor, the first light-emitting element, and the second light-emitting element. The connection line may be disposed between the first light-emitting element and the second light-emitting element disposed in the one subpixel, may be configured to cover an end of an anode of each of first light-emitting element and the second light-emitting element, and may be made of transparent conductive oxide.

Other detailed matters of the example embodiments are included in the detailed description and the drawings.

According to the present disclosure, it is possible to minimize a deterioration in reliability of the display device that occurs during the repair process.

According to the present disclosure, the plurality of light-emitting elements and the transistors may be more easily separated electrically during the repair process.

The advantages and effects according to the present disclosure are not limited to those described above, and additional advantages and effects are included in or may be obtained from the present disclosure.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF DRAWINGS

The accompanying drawings, which are included to provide a further understanding of the disclosure and are incorporated in and constitute a part of this application, illustrate example embodiments of the disclosure and together with the description serve to explain the principles of the disclosure. In the drawings:

FIG. 1 is a top plan view of a display device according to an example embodiment of the present disclosure;

FIG. 2A is an enlarged top plan view of a subpixel in which both a first light-emitting element and a second light-emitting element are normal in the display device according to an example embodiment of the present disclosure;

FIG. 2B is a cross-sectional view taken along line A-A′ in FIG. 2A;

FIG. 2C is a cross-sectional view taken along line A-A″ in FIG. 2A;

FIG. 2D is an enlarged view of area B in FIG. 2B;

FIG. 3A is an enlarged top plan view of a subpixel in which a first light-emitting element is defective in the display device according to an example embodiment of the present disclosure;

FIG. 3B is a cross-sectional view taken along line C-C′ in FIG. 3A;

FIG. 3C is an enlarged view of area D in FIG. 3B;

FIG. 4A is an enlarged top plan view of a subpixel in which a second light-emitting element is defective in the display device according to an example embodiment of the present disclosure;

FIG. 4B is a cross-sectional view taken along line E-E′ in FIG. 4A;

FIG. 5A is an enlarged top plan view of a subpixel in which both a first light-emitting element and a second light-emitting element are defective in the display device according to an example embodiment of the present disclosure;

FIG. 5B is a cross-sectional view taken along line F-F′ in FIG. 5A;

FIG. 6A is an enlarged top plan view of a subpixel in which both a first light-emitting element and a second light-emitting element are normal in a display device according to another example embodiment of the present disclosure;

FIG. 6B is a cross-sectional view taken along line G-G′ in FIG. 6A;

FIG. 6C is a cross-sectional view taken along line G-G″ in FIG. 6A;

FIG. 7A is an enlarged top plan view of a subpixel in which a first light-emitting element is defective in the display device according to another example embodiment of the present disclosure;

FIG. 7B is a cross-sectional view taken along line H-H′ in FIG. 7A;

FIG. 8A is an enlarged top plan view of a subpixel in which a second light-emitting element is defective in the display device according to another example embodiment of the present disclosure;

FIG. 8B is a cross-sectional view taken along line I-I′ in FIG. 8A;

FIG. 9A is an enlarged top plan view of a subpixel in which a first light-emitting element and a second light-emitting element are defective in the display device according to another example embodiment of the present disclosure;

FIG. 9B is a cross-sectional view taken along line J-J′ in FIG. 9A;

FIG. 10A is an enlarged top plan view of a subpixel in which all a first light-emitting element, a second light-emitting element, and a third light-emitting element are defective in the display device according to another example embodiment of the present disclosure; and

FIG. 10B is a cross-sectional view taken along line K-K′ in FIG. 10A.

### DETAILED DESCRIPTION

Advantages and features of the present disclosure and methods of achieving them will become apparent with reference to the example embodiments described below in detail in conjunction with the accompanying drawings. The present disclosure may, however, be embodied in different forms and should not be construed as limited to the example embodiments set forth herein. Rather, these example embodiments are provided so that this disclosure will be thorough and complete and will fully convey the scope of the present disclosure to those skilled in the art.

The shapes, sizes, ratios, angles, numbers, and the like, illustrated in the accompanying drawings for describing various example embodiments of the present disclosure, are merely given by way of example. Therefore, the present disclosure is not limited to such illustrated details in the drawings.

In the following description, where a detailed description of a relevant known function or configuration may unnecessarily obscure aspects of the present disclosure, a detailed description of such a known function or configuration may be omitted or be briefly discussed.

Where a term like “include,” “have,” or “consist of” is used, one or more other elements may be added unless the term is used with a more limiting term, such as “only” or the like. An element described in a singular form may include a plurality of elements, and vice versa, unless the context clearly indicates otherwise.

In construing an element, the element should be construed as including an error or tolerance range even where no explicit description of such an error or tolerance range is provided.

Where a positional relationship between two elements is described with such a term as “on,” “above,” “below,” “next,” or the like, one or more other elements may be located between the two elements unless the term is used with a more limiting term, such as “immediate(ly)” or “direct(ly).”

For example, where a first element is described as being positioned “on” a second element, the first element may be positioned above and contact the second element or may merely be above the second element with one or more additional elements disposed between the first and second elements.

Although terms “first,” “second,” and the like may be used herein to describe various elements, these elements should not be interpreted to be limited by these terms as they are not used to define a particular essence, order, sequence, precedence, or number of such elements. These terms are used only to refer to one element separately from another. For example, a first element could be termed a second element, and a second element could similarly be termed a first element, without departing from the scope of the present disclosure.

Like reference numerals generally denote like elements throughout the specification, unless otherwise specified.

A size and a thickness of each component illustrated in the drawing are illustrated for convenience of description, and the present disclosure is not limited to the size and the thickness of the component illustrated.

Features of various embodiments of the present disclosure may be partially or wholly coupled to or combined with each other, and may be operated, linked, or driven together in various ways as those skilled in the art can sufficiently understand. The embodiments of the present disclosure may be carried out independently from each other or may be carried out together in association with each other.

Hereinafter, various example embodiments of the present disclosure will be described in detail with reference to accompanying drawings.

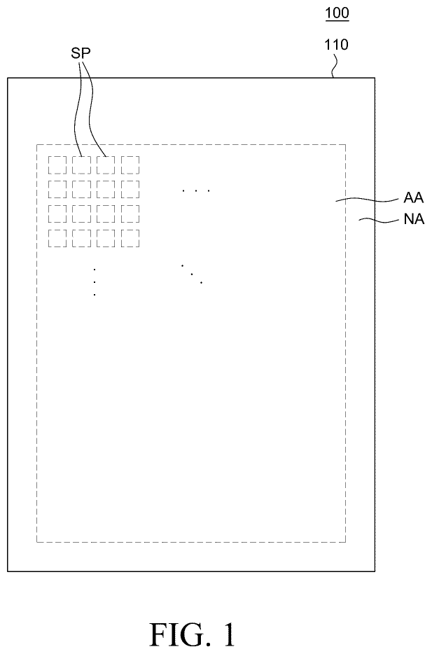

FIG. 1 is a top plan view of a display device according to an embodiment of the present disclosure. For convenience of description, FIG. 1 illustrates only a substrate 110 and a plurality of subpixels SP among various constituent elements of a display device 100.

The substrate 110 is a support member for supporting other constituent elements of the display device 100. The substrate 110 includes a display area AA and a non-display area NA. The substrate 110 may be made of an insulating material. For example, the substrate 110 may be made of glass, resin, or the like. In addition, the substrate 110 may include plastic such as polymer or polyimide (PI) and may be made of a material having flexibility.

The display area AA of the substrate 110 is an area in which images are displayed. The display area AA may include the plurality of subpixels SP for displaying images, and a pixel circuit configured to operate the plurality of subpixels SP. The pixel circuit may include various thin-film transistors, storage capacitors, lines, and the like for operating the subpixels SP.

The non-display area NA is an area in which no image is displayed. Various lines, drive ICs, and the like for operating the subpixels SP disposed in the display area AA are disposed in the non-display area NA. For example, various drive ICs such as a gate driver IC and a data driver IC may be disposed in the non-display area NA.

Meanwhile, FIG. 1 illustrates that the non-display area NA surrounds the display area AA. However, the non-display area NA may be an area extending from one side of the display area AA. However, the present disclosure is not limited thereto.

The plurality of subpixels SP is disposed in the display area AA of the substrate 110. The plurality of subpixels SP is each an individual unit configured to emit light. A light-emitting element and a pixel circuit are formed in each of the plurality of subpixels SP. For example, the plurality of subpixels SP may include a red subpixel, a green subpixel, a blue subpixel, and a white subpixel. However, the present disclosure is not limited thereto.

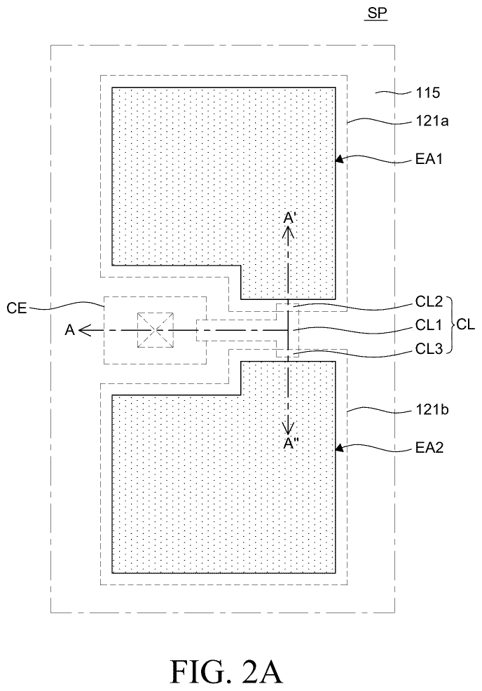

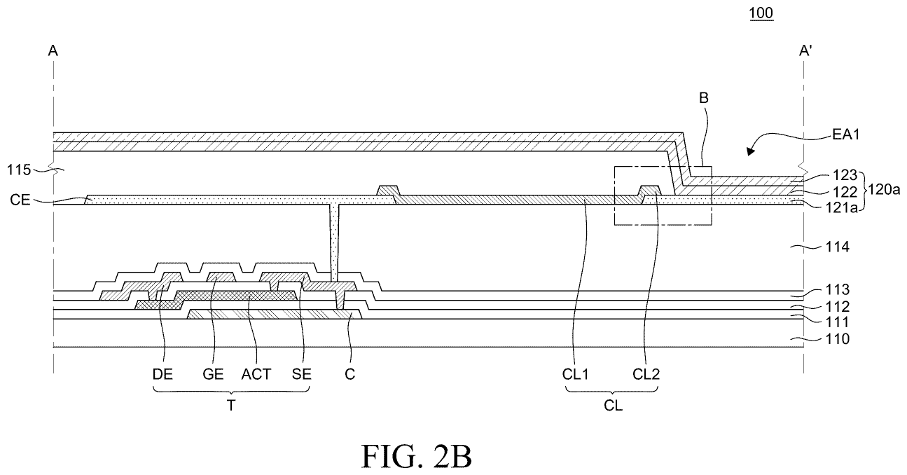

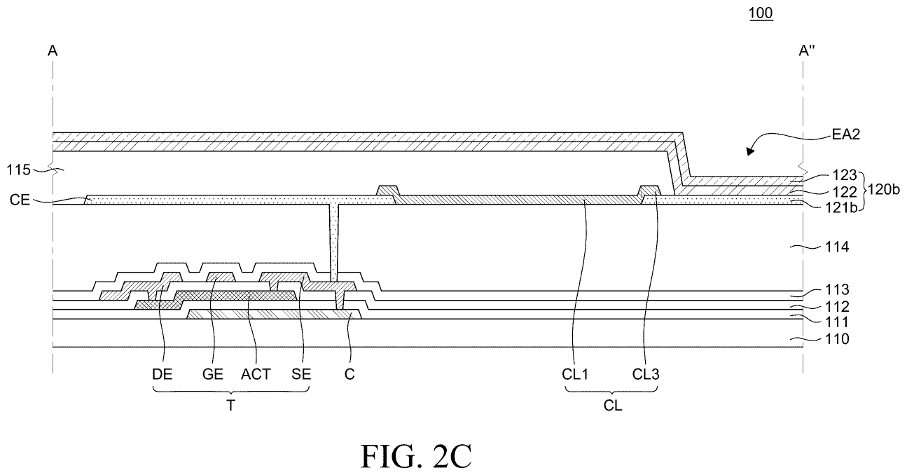

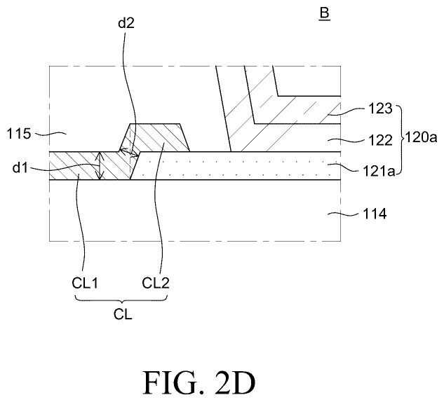

Hereinafter, a subpixel, in which all the plurality of light-emitting elements are normal in the display device according to the embodiment of the present disclosure, will be described in more detail with reference to FIGS. 2A to 2D.

FIG. 2A is an enlarged top plan view of a subpixel in which both a first light-emitting element and a second light-emitting element are normal in the display device according to the embodiment of the present disclosure. FIG. 2B is a cross-sectional view taken along line A-A′ in FIG. 2A. FIG. 2C is a cross-sectional view taken along line A-A″ in FIG. 2A. FIG. 2D is an enlarged view of area B in FIG. 2B. FIG. 2A is a top plan view of the subpixel in which both the first light-emitting element and the second light-emitting element are normal among the plurality of subpixels. For convenience of illustration, FIG. 2A illustrates only a first anode, a second anode, a connection electrode, a connection line, and a bank among various constituent elements of the display device.

The plurality of subpixels SP each include a light-emitting area and a circuit area.

The light-emitting area is an area that may independently emit light with a single type of color. The light-emitting element may be disposed in the light-emitting area. The plurality of subpixels SP may include a first subpixel, a second subpixel, a third subpixel, and a fourth subpixel that emit light beams with different colors. For example, the light-emitting area of the first subpixel may be a red light-emitting area for emitting red light, the light-emitting area of the second subpixel may be a white light-emitting area for emitting white light, the light-emitting area of the third subpixel may be a blue light-emitting area for emitting blue light, and the light-emitting area of the fourth subpixel may be a green light-emitting area for emitting green light. However, the present disclosure is not limited thereto, and the colors of the light beams implemented in the plurality of light-emitting areas and the arrangement of the plurality of light-emitting areas may vary in accordance with design.

The circuit area is an area in which the pixel circuit for operating the plurality of light-emitting elements is disposed. A plurality of transistors and capacitors may be disposed in the circuit area. For example, in case that the pixel circuit of the subpixel SP has a 3T1C structure, three transistors and one storage capacitor may be disposed. However, the present disclosure is not limited thereto.

With reference to FIG. 2A, the plurality of light-emitting areas EA1 and EA2 are disposed in each of the subpixels SP. Further, in each of the subpixels SP, the plurality of light-emitting elements 120a and 120b are disposed to respectively correspond to the plurality of light-emitting areas EA1 and EA2. The plurality of light-emitting areas EA1 and EA2 may be defined by a bank 115 disposed to cover ends of anodes 121a and 121b of the plurality of light-emitting elements 120a and 120b.

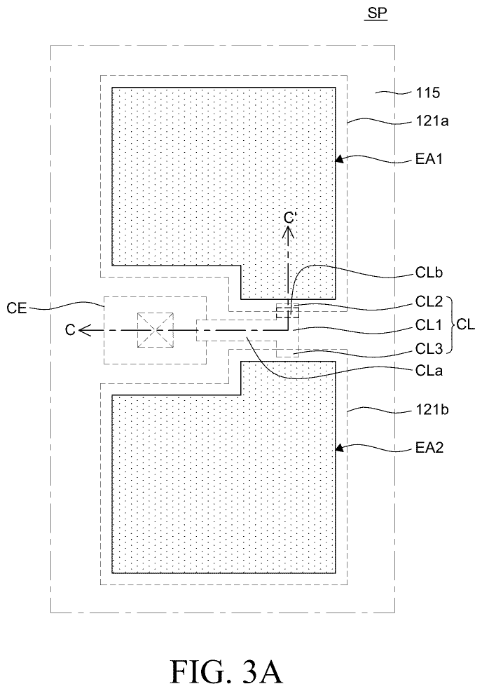

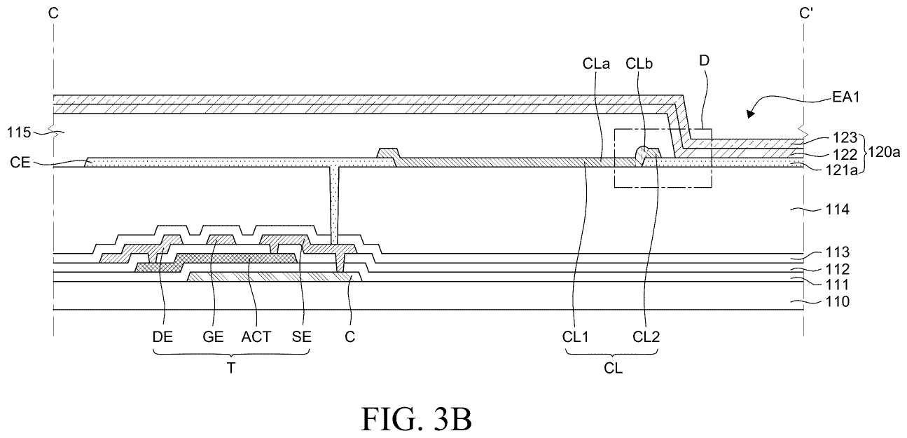

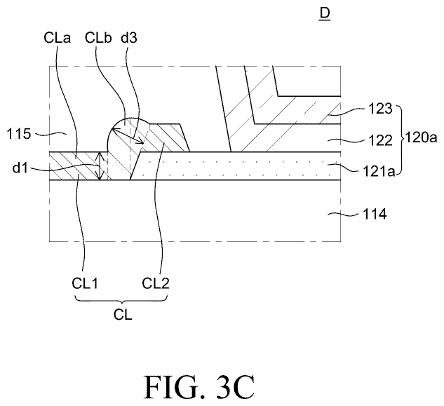

The plurality of light-emitting elements 120a and 120b disposed in each of the subpixels SP include a first light-emitting element 120a and a second light-emitting element 120b. The first light-emitting element 120a and the second light-emitting element 120b emit light beams with the same color. The first light-emitting element 120a and the second light-emitting element 120b may be disposed to share one pixel circuit. Therefore, the first light-emitting element 120a and the second light-emitting element 120b may be configured to repair a luminance defect or a dark spot defect of the subpixel SP. However, a method of repairing a defective subpixel SP will be described below in detail with reference to FIGS. 3A to 5B.

With reference to FIGS. 2B and 2C, a buffer layer 111, a gate insulation layer 112, a transistor T, a passivation layer 113, a planarization layer 114, a connection electrode CE, the first light-emitting element 120a, the second light-emitting element 120b, a connection line CL, and the bank 115 are sequentially disposed on the substrate 110 in the subpixel SP.

The buffer layer 111 is disposed on the substrate 110. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto, and the buffer layer 111 may be excluded in accordance with the type of substrate 110 or the type of thin-film transistor.

The transistor T is disposed in the circuit area in each of the plurality of subpixels SP. The transistor T includes a gate electrode GE, a source electrode SE, a drain electrode DE, and an active layer ACT.

First, the active layer ACT is disposed on the buffer layer 111. The active layer ACT may be made of a semiconductor material such as an oxide semiconductor, amorphous silicon, or polysilicon. However, the present disclosure is not limited thereto. For example, in case that the active layer ACT is made of oxide semiconductor, the active layer ACT may include the channel area, the source area, and the drain area, and the source area and the drain area may be areas having conductivity. However, the present disclosure is not limited thereto.

The gate insulation layer 112 is disposed on the active layer ACT. The gate insulation layer 112 may be a layer for insulating the gate electrode GE and the active layer ACT and made of an insulating material. For example, the gate insulation layer 112 may be configured as a single layer or multilayer made of silicon oxide (SiOx) or silicon nitride (SiNx). However, the present disclosure is not limited thereto.

The gate electrode GE is disposed on the gate insulation layer 112. The gate electrode GE is disposed on the gate insulation layer 112 and overlaps the active layer ACT. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The source electrode SE and the drain electrode DE are disposed on the gate insulation layer 112 and spaced apart from each other. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

For example, the drain electrode DE may be electrically connected to a high-potential power line through contact holes formed in the gate insulation layer 112 and the buffer layer 111.

The source electrode SE may be electrically connected to the connection electrode CE, the connection line CL, and the anodes 121a and 121b of the plurality of light-emitting elements 120a and 120b through a contact hole formed in the planarization layer 114 to be described below, such that the source electrode SE may transmit drive currents to the anodes 121a and 121b of the plurality of light-emitting elements 120a and 120b. Further, with reference to FIGS. 2B and 2C, the source electrode SE may be electrically connected to a capacitor electrode C, which is disposed between the substrate 110 and the buffer layer 111, through contact holes formed in the gate insulation layer 112 and the buffer layer 111. However, the present disclosure is not limited thereto.

The storage capacitor may be disposed in the circuit area in each of the plurality of subpixels SP. The storage capacitor may store a voltage between the gate electrode GE and the source electrode SE of the transistor T so that the light-emitting element may continuously maintain the same state during a single frame. The storage capacitor includes a first capacitor electrode C.

With reference to FIGS. 2B and 2C, the first capacitor electrode C is disposed between the substrate 110 and the buffer layer 111 in each of the plurality of subpixels SP. The first capacitor electrode C may be disposed to be closest to the substrate 110 among the conductive constituent elements disposed on the substrate 110. The first capacitor electrode C may be electrically connected to the source electrode SE through contact holes formed in the buffer layer 111 and the gate insulation layer 112. The first capacitor electrode C may be made of an electrically conductive material, for example, an electrically conductive material such as copper (Cu), aluminum (Al), molybdenum (Mo), nickel (Ni), titanium (Ti), chromium (Cr), or an alloy thereof. However, the present disclosure is not limited thereto.

Meanwhile, although not illustrated in the drawings, a second capacitor electrode may be further disposed on the buffer layer 111. The second capacitor electrode may be disposed on the first capacitor electrode C and overlap the first capacitor electrode C. For example, the second capacitor electrode may be integrated with the source electrode SE and electrically connected to the source electrode SE. Further, the second capacitor electrode may be electrically connected to the gate electrode GE through a contact hole formed in the gate insulation layer 112. Therefore, the second capacitor electrode may be electrically connected to the source electrode SE and the gate electrode GE.

Meanwhile, the first capacitor electrode C may serve as a light-blocking layer that blocks light entering the active layer ACT of the transistor T. Therefore, the first capacitor electrode C may be referred to as a light-blocking layer. For example, in case that the light is emitted to the active layer ACT, a leakage current occurs, which may degrade the reliability of the transistor T. Therefore, the first capacitor electrode C made of an opaque conductive material may be disposed below the active layer ACT and block light entering the active layer ACT from the lower side of the substrate 110, which may improve the reliability of the transistor T.

Next, the passivation layer 113 is disposed on the transistor T and the storage capacitor. The passivation layer 113 is an insulation layer for protecting the components disposed below the passivation layer 113. For example, the passivation layer 113 may be configured as a single layer or multilayer made of silicon oxide (SiOx) or silicon nitride (SiNx). However, the present disclosure is not limited thereto. In addition, the passivation layer 113 may be excluded in accordance with the embodiments.

The planarization layer 114 is disposed on the passivation layer 113. The planarization layer 114 is an insulation layer for planarizing an upper portion of the substrate 110 on which the transistor T and the storage capacitor are disposed. The planarization layer 114 may be an organic layer made of an organic material. For example, the planarization layer 114 may be configured as a single layer or multilayer made of an organic material, for example, polyimide or photo acrylic. However, the present disclosure is not limited thereto.

The plurality of light-emitting elements 120a and 120b are disposed in each of the plurality of subpixels SP. The plurality of light-emitting elements 120a and 120b are disposed on the planarization layer 114 in each of the plurality of subpixels SP. The plurality of light-emitting elements 120a and 120b include the anodes 121a and 121b, light-emitting layers 122, and cathodes 123.

With reference to FIGS. 2A to 2C, a first anode 121a and a second anode 121b are disposed on the planarization layer 114 and correspond to the plurality of light-emitting areas EA1 and EA2. Because the first anode 121a and the second anode 121b supply positive holes to the light-emitting layers 122, the first anode 121a and the second anode 121b may be made of an electrically conductive material with a high work function. For example, the first anode 121a and the second anode 121b may each be made of a transparent conductive material such as indium tin oxide (ITO) or indium zinc oxide (IZO). However, the present disclosure is not limited thereto.

Meanwhile, in case that the display device 100 according to the embodiment of the present disclosure is a top emission type display device, a reflective layer, which is made of a metallic material, e.g., a material such as aluminum (Al) or silver (Ag) with excellent reflection efficiency, may be additionally provided below the first anode 121a and the second anode 121b so that the light emitted from the light-emitting layer 122 is reflected by the first anode 121a and the second anode 121b and propagates upward, i.e., toward the cathode 123. For example, the first anode 121a and the second anode 121b may each have a structure in which indium tin oxide (ITO), silver (Ag), and indium tin oxide (ITO) are sequentially stacked. However, the present disclosure is not limited thereto. On the contrary, in case that the display device 100 is a bottom emission type display device, the first anode 121a and the second anode 121b may be made of only a transparent conductive material.

The bank 115 is disposed on the first anode 121a and the second anode 121b. The bank 115 may be disposed in the remaining area excluding the plurality of light-emitting areas EA1 and EA2. The bank 115 may be disposed at the boundaries between the plurality of subpixels SP and disposed in the circuit areas of the plurality of subpixels SP and reduce a color mixture of light beams emitted from the plurality of subpixels SP. The bank 115 may include an opening portion through which the first and second anodes 121a and 121b corresponding to the plurality of light-emitting areas EA1 and EA2 are at least partially exposed. The bank 115 may be made of an organic insulating material. For example, the bank 115 may be made of polyimide-based resin, acryl-based resin, or benzocyclobutene (BCB)-based resin. However, the present disclosure is not limited thereto.

The light-emitting layer 122 is disposed on the first anode 121a, the second anode 121b, and the bank 115 in each of the plurality of light-emitting areas EA1 and EA2. For example, the light-emitting layer 122 may be configured as a single layer over the plurality of subpixels SP. That is, the light-emitting layers 122 of the plurality of subpixels SP may be connected to and integrated with one another. The light-emitting layer 122 may be configured as a single light-emitting layer. The light-emitting layer 122 may also have a structure in which a plurality of light-emitting layers configured to emit light beams with different colors is stacked. The light-emitting layer 122 may further include organic material layers such as a hole injection layer, a hole transport layer, an electron transport layer, and an electron injection layer. For example, in case that the light-emitting layer 122 is the light-emitting layer configured to emit white light, the light beam emitted from the light-emitting layer 122 may be converted into light beams with various colors by a plurality of color filters. However, the present disclosure is not limited thereto.

The cathode 123 is disposed on the light-emitting layer 122. Because the cathode 123 supplies electrons to the light-emitting layer 122, the cathode 123 may be made of an electrically conductive material having a low work function. The cathode 123 may be configured as a single layer over the plurality of subpixels SP. That is, the cathodes 123 of the plurality of subpixels SP may be connected to and integrated with one another. For example, the cathode 123 may be made of an electrically transparent conductive material such as indium tin oxide (ITO) or indium zinc oxide (IZO) or made of an alloy of ytterbium (Yb). The cathode 123 may further include a metal doping layer. However, the present disclosure is not limited thereto. Meanwhile, although not illustrated in the drawings, the cathode 123 of each of the plurality of light-emitting elements 120a and 120b may be electrically connected to a low-potential power line and supplied with a low-potential power voltage.

With reference to FIGS. 2A to 2C, the connection electrode CE is disposed on the planarization layer 114. The connection electrode CE may be disposed on the transistor T and configured to electrically connect the transistor T, the first anode 121a, and the second anode 121b. For example, the connection electrode CE may be electrically connected to the source electrode SE of the transistor T, the connection line CL, and the anodes 121a and 121b of the plurality of light-emitting elements 120a and 120b. However, the present disclosure is not limited thereto.

The connection electrode CE is disposed on the same layer as the anodes 121a and 121b of the plurality of light-emitting elements 120a and 120b. The connection electrode CE may be formed by the same process and made of the same material as the anodes 121a and 121b of the plurality of light-emitting elements 120a and 120b. However, the present disclosure is not limited thereto. For example, the connection electrode CE may be made of a transparent conductive material such as indium tin oxide (ITO) or indium zinc oxide (IZO). However, the present disclosure is not limited thereto.

The connection line CL is disposed on the connection electrode CE and the anodes 121a and 121b of the plurality of light-emitting elements 120a and 120b. For example, the connection line CL, the connection electrode CE and the anodes 121a and 121b of the plurality of light-emitting elements 120a and 120b may be disposed on the planarization layer 114. The connection line CL may be configured to adjoin the transistor T and the plurality of light-emitting elements 120a and 120b. A part of the connection line CL is disposed between the first light-emitting element 120a and the second light-emitting element 120b and disposed to cover an end of the first anode 121a and an end of the second anode 121b. Further, another part of the connection line CL is disposed to cover an end of the connection electrode CE. Therefore, the connection line CL may adjoin the connection electrode CE, the first light-emitting element 120a, and the second light-emitting element 120b and electrically connect the transistor T and the plurality of light-emitting elements 120a and 120b. Therefore, the connection line CL may serve as a repair part that repairs the subpixel SP with a bright spot defect or a dark spot defect by selectively blocking the electrical connection between the plurality of light-emitting elements 120a and 120b and the transistor T. However, a method of repairing a defective subpixel SP with a bright spot defect or a dark spot defect will be described below in detail with reference to FIGS. 3A to 5B.

Meanwhile, FIGS. 2A to 2D illustrate a normal subpixel SP that does not have a defect and is not subjected to the repair process. In this case, in case that all the plurality of light-emitting elements disposed in the subpixel SP are normal, the repair process is not performed on the connection line CL disposed in the subpixel SP, such that the entire connection line CL may be conductive.

With reference to FIGS. 2A to 2C, the connection line CL includes a first portion CL1, a second portion CL2, and a third portion CL3. The first portion CL1 is a portion that adjoins the connection electrode CE and extends between the first light-emitting element 120a and the second light-emitting element 120b. The second portion CL2 is a portion that extends from the first portion CL1 and covers an end of the first anode 121a of the first light-emitting element 120a. The third portion CL3 is a portion that extends from the first portion CL1 and covers an end of the second anode 121b of the second light-emitting element 120b.

The connection line CL may be made of transparent conductive oxide. For example, the connection line CL may be made of a transparent conductive material, such as indium zinc oxide (IZO) and indium gallium zinc oxide (IGZO), including indium (In). However, the present disclosure is not limited thereto.

Meanwhile, the connection line CL is disposed after the connection electrode CE, the first anode 121a, and the second anode 121b are formed. Therefore, for example, the connection line CL may be disposed after a step of crystallizing a material that constitutes the connection electrode CE, the first anode 121a, and the second anode 121b. Therefore, even though wet etching is used during a process of disposing the connection line CL on the connection electrode CE, the first anode 121a, and the second anode 121b, the wet etching may not affect the connection electrode CE, the first anode 121a, and the second anode 121b.

With reference to FIG. 2D, the connection line CL may be disposed to have partially different thicknesses because of step differences between the end of the connection electrode CE, the end of the first anode 121a, the end of the second anode 121b, and a top surface of the planarization layer 114. Specifically, a second thickness d2, which is a thickness of a portion of the connection line CL that adjoins the end of the connection electrode CE and the ends of the anodes 121a and 121b of the plurality of light-emitting elements 120a and 120b, may be equal to or smaller than a first thickness d1 that is a thickness of the remaining portion. For example, the second thickness d2 may be about ⅔ of the first thickness d1. However, the present disclosure is not limited thereto. As described above, in case that all the plurality of light-emitting elements disposed in the subpixel SP are normal, the thickness of the portion of the connection line CL, which adjoins the end of the connection electrode CE, the end of the first anode 121a, and the end of the second anode 121b, may be equal to or smaller than the thickness of the remaining portion.

Meanwhile, although not illustrated in the drawings, an encapsulation layer, an encapsulation substrate, and a plurality of color filters may be further disposed on the plurality of light-emitting elements 120a and 120b.

The encapsulation layer is disposed on the plurality of light-emitting elements 120a and 120b. The encapsulation layer may cover the plurality of light-emitting elements 120a and 120b and protect the plurality of light-emitting elements 120a and 120b from external moisture, oxygen, impact, and the like. The encapsulation layer may be formed by alternately stacking a plurality of inorganic layers and a plurality of organic layers. For example, the inorganic layer may be made of an inorganic material such as silicon nitride (SiNx), silicon oxide (SiOx), or aluminum oxide (AlOx). The organic layer may be made of epoxy-based polymer or acrylic polymer. However, the present disclosure is not limited thereto.

The encapsulation substrate is disposed on the encapsulation layer. The encapsulation substrate, together with the encapsulation layer, may protect the plurality of light-emitting elements 120a and 120b from external moisture, oxygen, impact, and the like. For example, the encapsulation substrate may be made of a transparent insulating material. However, the encapsulation substrate may be made of a metallic material. However, the present disclosure is not limited thereto.

The plurality of color filters may be disposed on the plurality of light-emitting elements 120a and 120b. For example, the plurality of color filters may be disposed between the encapsulation layer and the encapsulation substrate. However, the present disclosure is not limited thereto.

The plurality of color filters may include a red color filter, a green color filter, a blue color filter, and the like. For example, the red color filter may be disposed in the light-emitting area of the first subpixel and convert white light, which is emitted from the first subpixel, into red light. The blue color filter may be disposed in the light-emitting area of the third subpixel and convert white light, which is emitted from the third subpixel, into blue light. The green color filter may be disposed in the light-emitting area of the fourth subpixel and convert white light, which is emitted from the fourth subpixel, into green light. Further, no separate color filter may be disposed on the second subpixel that is a white subpixel. White light, which is emitted from the light-emitting element of the second subpixel, may propagate to the outside of the display device 100 in an intact manner and display a white image.

Hereinafter, a method of repairing a subpixel SP in which a defective light-emitting element is disposed in the display device according to the embodiment of the present disclosure will be described in more detail with reference to FIGS. 3A to 5B.

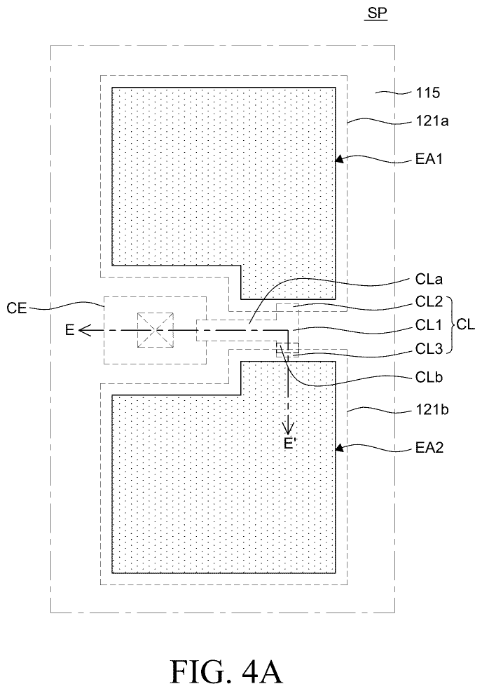

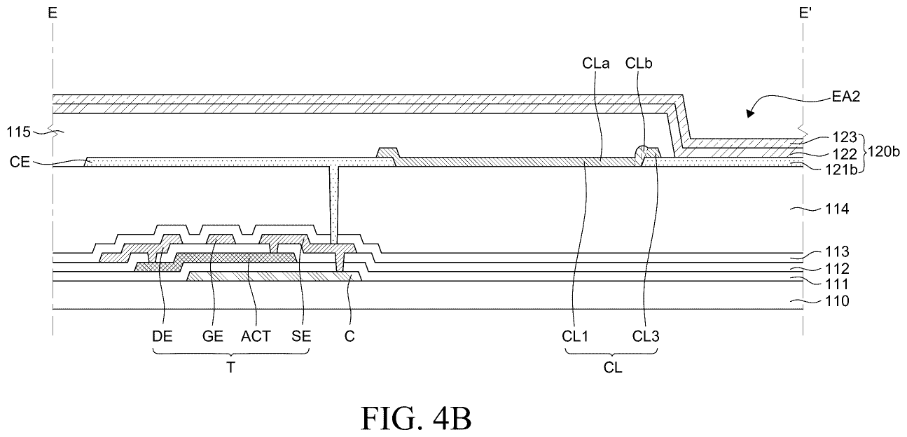

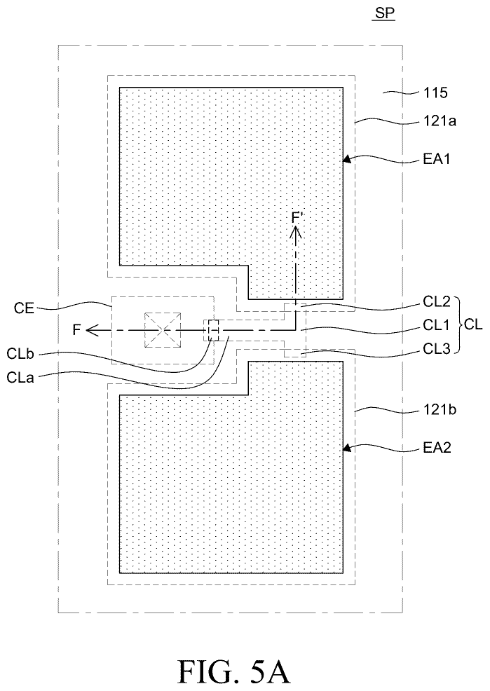

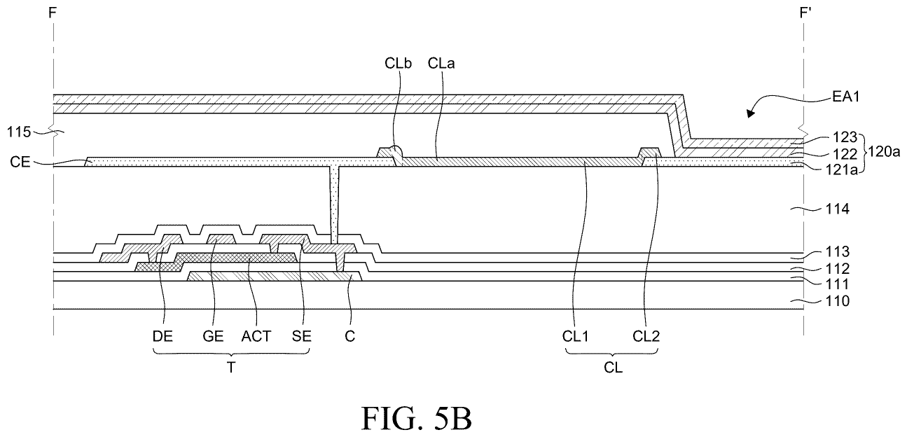

FIG. 3A is an enlarged top plan view of a subpixel in which a first light-emitting element is defective in the display device according to the embodiment of the present disclosure. FIG. 3B is a cross-sectional view taken along line C-C′ in FIG. 3A. FIG. 3C is an enlarged view of area D in FIG. 3B. FIG. 4A is an enlarged top plan view of a subpixel in which a second light-emitting element is defective in the display device according to the embodiment of the present disclosure. FIG. 4B is a cross-sectional view taken along line E-E′ in FIG. 4A. FIG. 5A is an enlarged top plan view of a subpixel in which both a first light-emitting element and a second light-emitting element are defective in the display device according to the embodiment of the present disclosure. FIG. 5B is a cross-sectional view taken along line F-F′ in FIG. 5A.

For example, during the process of manufacturing the display device, a short circuit (A-C short) may occur between the anode and the cathode by foreign substances remaining between the anode and the cathode of the light-emitting element, thus there may occur a dark spot defect in which electric current is not applied to the light-emitting element or a bright spot defect in which the light-emitting element continuously emits light. Therefore, it is possible to repair the display device so that a bright spot defect or a dark spot defect of a defective light-emitting element in a final product is not visually recognized by electrically disconnecting the transistor and the light-emitting element that has a bright spot defect or a dark spot defect among the plurality of light-emitting elements connected to one transistor.

With reference to FIGS. 3A to 5B, in the display device 100 according to the embodiment of the present disclosure, the connection line CL of the subpixel SP, which has a bright spot defect or a dark spot defect, includes a low-resistance portion CLa and a high-resistance portion CLb.

The low-resistance portion CLa is a portion that is not subjected to a laser irradiation process for repairing the connection line CL. The low-resistance portion CLa is a portion that is in the same state as a portion excluding a portion that adjoins the end of the connection electrode CE, the end of the first anode 121a, and the end of the second anode 121b in the connection line CL of the normal subpixel SP. That is, a thickness of the low-resistance portion CLa may be equal to the first thickness d1 of the connection line CL.

The high-resistance portion CLb is a portion that is subjected to the laser irradiation process for repairing the connection line CL. In case that at least one of the plurality of light-emitting elements 120a and 120b is defective, at least one of the first portion CL1, the second portion CL2, and the third portion CL3 of the connection line CL may include the high-resistance portion CLb.

The high-resistance portion CLb is disposed on the portion of the connection line CL that adjoins the end of at least one of the connection electrode CE, the first anode 121a, and the second anode 121b. That is, the high-resistance portion CLb may be formed by irradiating the portion of the connection line CL, which is disposed with the second thickness d2, with laser beams.

For example, the high-resistance portion CLb may be formed by a process in which a diffusion phenomenon in which a temperature of the connection line CL is increased by laser beams and distances between indium (In) particles included in the connection line CL are increased occurs, and a volume of the corresponding portion is also increased. For example, the thickness of the high-resistance portion CLb may be increased by about 10% to 20% in comparison with the state made before the laser irradiation. However, the present disclosure is not limited thereto.

In addition, a thickness of the high-resistance portion CLb may be larger than a thickness of the low-resistance portion CLa. For example, as illustrated in FIG. 3C, a third thickness d3, which is a thickness of the high-resistance portion CLb, may be larger than the first thickness d1. However, the present disclosure is not limited thereto.

In this case, in the high-resistance portion CLb in which the distances between the indium (In) particles are increased, the movement of electric current decreases, such that the high-resistance portion CLb may have higher resistance than the low-resistance portion CLa. Therefore, the connection line CL, in which the high-resistance portion CLb is disposed, may be configured to substantially electrically disconnect the plurality of light-emitting elements 120a and 120b and the transistor T.

Meanwhile, because the high-resistance portion CLb in the connection line CL is a portion where the distances between the indium (In) particles are increased by the laser irradiation, an indium (In) density of the high-resistance portion CLb may be lower than an indium (In) density of the low-resistance portion CLa. That is, the indium (In) density of the low-resistance portion CLa may be higher than the indium (In) density of the high-resistance portion CLb.

With reference to FIGS. 3A to 5B, the high-resistance portion CLb may be disposed to adjoin the end of the connection electrode CE or disposed to adjoin the end of the first anode 121a or the end of the second anode 121b. In this case, the connection line CL, which adjoins the end of the connection electrode CE, the end of the first anode 121a, and the end of the second anode 121b in a state in which the connection line CL is not irradiated with laser beams, may have the second thickness d2 smaller than the first thickness d1, which is a thickness of another portion, by step differences between the end of the connection electrode CE, the end of the first anode 121a, and the end of the second anode 121b. Further, in case that the connection line CL disposed with the second thickness d2 is irradiated with laser beams, the indium (In) particles included in the connection line CL are more sensitive to the laser beams, such that diffusion of indium (In) particles may be further facilitated in comparison with the portion disposed with the first thickness d1. Therefore, the high-resistance portion CLb is disposed to adjoin the end of the connection electrode CE or disposed to adjoin the end of the first anode 121a or the end of the second anode 121b, such that the plurality of light-emitting elements 120a and 120b and the transistor T may be more easily electrically disconnected.

Hereinafter, a method of repairing the subpixel SP, in which defects occur in various cases, will be described more specifically.

First, with reference to FIGS. 3A to 3C, in case that a bright spot defect or a dark spot defect occurs on the first light-emitting element 120a, the second portion CL2 of the connection line CL, which adjoins the end of the first anode 121a of the first light-emitting element 120a, is irradiated with laser beams. Further, the distances between the indium (In) particles included in the connection line CL are increased by the laser irradiation, and the movement of electric current decreases, such that the high-resistance portion CLb, which is a portion with an increased resistance value, is formed. Therefore, because the first light-emitting element 120a, which has a defect, is electrically disconnected from the transistor T by the high-resistance portion, the defect occurring on the first light-emitting element 120a in the subpixel SP may not be visually recognized, and the subpixel SP may be repaired.

Next, with reference to FIGS. 4A and 4B, in case that a bright spot defect or a dark spot defect occurs on the second light-emitting element 120b, the third portion CL3 of the connection line CL, which adjoins the end of the second anode 121b of the second light-emitting element 120b, is irradiated with laser beams. Further, the distances between the indium (In) particles included in the connection line CL are increased by the laser irradiation, and the movement of electric current decreases, such that the high-resistance portion CLb, which is a portion with an increased resistance value, is formed. Therefore, because the second light-emitting element 120b, which has a defect, is electrically disconnected from the transistor T by the high-resistance portion CLb, the defect occurring on the second light-emitting element 120b in the subpixel SP may not be visually recognized, and the subpixel SP may be repaired.

Lastly, with reference to FIGS. 5A and 5B, in case that a bright spot defect or a dark spot defect occurs on both the first light-emitting element 120a and the second light-emitting element 120b, the first portion CL1 of the connection line CL, which adjoins the end of the connection electrode CE, is irradiated with laser beams. Further, the distances between the indium (In) particles included in the connection line CL are increased by the laser irradiation, and the movement of electric current decreases, such that the high-resistance portion CLb, which is a portion with an increased resistance value, is formed. Therefore, because the first light-emitting element 120a and the second light-emitting element 120b, which have defects, are electrically disconnected from the transistor T by the high-resistance portion CLb, the defects occurring on the first light-emitting element 120a and the second light-emitting element 120b in the subpixel SP may not be visually recognized, and the subpixel SP may be repaired.

In the display device configured such that the plurality of light-emitting areas is disposed in one subpixel to repair a bright spot defect or a dark spot defect, the bright spot defect or the dark spot defect may be repaired by a process of selectively separating lines or electrodes that electrically connect the plurality of light-emitting areas and the transistor connected to the plurality of light-emitting areas. In this case, for example, the method of electrically disconnecting the plurality of light-emitting areas and the transistor may be performed by a method of physically removing the lines or electrodes by emitting laser beams.

However, in case that the lines or electrodes are physically removed to repair a bright spot defect or a dark spot defect of the subpixel, the arrangement structure between the surrounding constituent elements is deformed by volumes of the removed lines or electrodes, which may cause a problem of a deterioration in reliability of the display device. Meanwhile, the problem of a bright spot defect or a dark spot defect of the subpixel and the deformation of the arrangement structure, which additionally occurs during the repair process, may become more severe in the top emission type display device in which a larger number of constituent elements are disposed above the light-emitting elements in the plurality of light-emitting areas.

Therefore, in the display device 100 according to the embodiment of the present disclosure, the connection line CL is disposed to connect the connection electrode CE, the first anode 121a, and the second anode 121b, and the high-resistance portion CLb is disposed on the connection line CL of the subpixel SP in which a defective light-emitting element is disposed, which may minimize a deterioration in reliability of the display device 100 that occurs during the repair process.

Specifically, in the display device 100 according to the embodiment of the present disclosure, the connection line CL may adjoin the end of the connection electrode CE, the end of the first anode 121a, and the end of the second anode 121b and electrically connect the transistor T and the plurality of light-emitting elements 120a and 120b. Therefore, the connection line CL may serve as a repair part that repairs the subpixel SP, in which the light-emitting element with a dark spot defect or a bright spot defect is disposed, by selectively blocking the electrical connection between the plurality of light-emitting elements 120a and 120b and the transistor T.

Further, in case that at least one of the plurality of light-emitting elements 120a and 120b is defective, at least one of the first portion CL1, the second portion CL2, and the third portion CL3 of the connection line CL may include the high-resistance portion CLb. In this case, because the high-resistance portion CLb increases the distances between the indium (In) particles and decreases the movement of electric current, the connection line CL, in which the high-resistance portion CLb is disposed, may be configured to substantially electrically disconnect the plurality of light-emitting elements 120a and 120b and the transistor T. That is, the connection line CL of the display device 100 according to the embodiment of the present disclosure may be configured to substantially electrically disconnect the plurality of light-emitting elements 120a and 120b and the transistor T even without being physically removed. Therefore, it is possible to minimize the problem of the deformation of the arrangement structure of the surrounding constituent elements that occurs when the connection line CL is physically removed during the repair process of electrically disconnecting the transistor T and the defective light-emitting element. Therefore, in the display device 100 according to the embodiment of the present disclosure, the connection line CL is disposed to connect the connection electrode CE, the first anode 121a, and the second anode 121b, and the high-resistance portion CLb is disposed on the connection line CL of the subpixel SP in which a defective light-emitting element is disposed, which may minimize a deterioration in reliability of the display device 100 that occurs during the repair process.

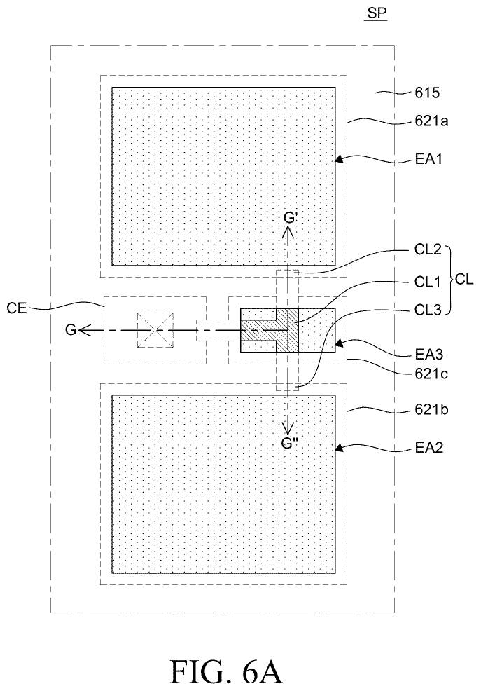

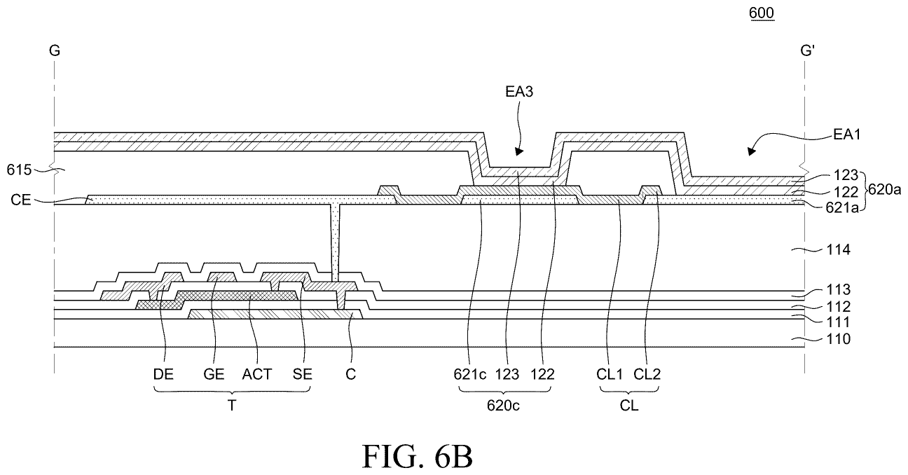

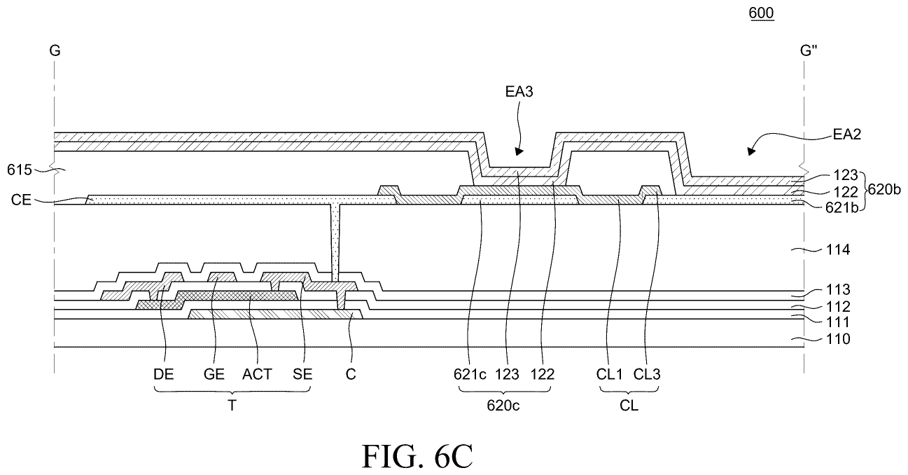

Hereinafter, a subpixel in which all the plurality of light-emitting elements are normal in a display device according to another embodiment of the present disclosure will be described in detail with reference to FIGS. 6A to 6C.

FIG. 6A is an enlarged top plan view of a subpixel in which both a first light-emitting element and a second light-emitting element are normal in a display device according to another embodiment of the present disclosure. FIG. 6B is a cross-sectional view taken along line G-G′ in FIG. 6A. FIG. 6C is a cross-sectional view taken along line G-G″ in FIG. 6A. A display device 600 in FIGS. 6A to 6C is substantially identical in configuration to the display device 100 in FIGS. 1 to 5B, except that a third light-emitting element 620c is further disposed in each of the subpixels SP. Therefore, repeated descriptions of the identical components will be omitted.

With reference to FIGS. 6A to 6C, a first light-emitting area EA1, a second light-emitting area EA2, and a third light-emitting area EA3 are disposed in each of the subpixels SP of the display device 600 according to another embodiment of the present disclosure.

Further, the third light-emitting element 620c is disposed to correspond to the third light-emitting area EA3 in each of the subpixels SP. The third light-emitting element 620c is disposed between a first light-emitting element 620a and a second light-emitting element 620b. The third light-emitting element 620c emits light with the same color as the light emitted from the first light-emitting element 620a and the light emitted from the second light-emitting element 620b. The first light-emitting element 620a, the second light-emitting element 620b, and the third light-emitting element 620c may be disposed to share one pixel circuit. Therefore, the first light-emitting element 620a, the second light-emitting element 620b, and the third light-emitting element 620c may be configured to repair a luminance defect or a dark spot defect of the subpixel SP.

The third light-emitting element 620c includes a third anode 621c, the light-emitting layer 122, and the cathode 123.

With reference to FIGS. 6A to 6C, the third anode 621c is disposed on the planarization layer 114 and corresponds to the third light-emitting area EA3. Because the third anode 621c supplies positive holes to the light-emitting layer 122, the third anode 621c may be made of an electrically conductive material with a high work function.

A bank 615 is disposed on the third anode 621c. The bank 615 may be disposed in the remaining area excluding the plurality of light-emitting areas EA1, EA2, and EA3. The bank 615 may include an opening portion through which a first anode 621a, a second anode 621b, and the third anode 621c corresponding to the plurality of light-emitting areas EA1, EA2, and EA3 are at least partially exposed. However, the present disclosure is not limited thereto.

The light-emitting layer 122 is disposed on the third anode 621c and the bank 615. For example, the light-emitting layer 122 may be configured as a single layer over the plurality of subpixels SP. That is, the light-emitting layers 122 of the plurality of subpixels SP may be connected to and integrated with one another. The light-emitting layer 122 may be configured as a single light-emitting layer. The light-emitting layer 122 may also have a structure in which a plurality of light-emitting layers configured to emit light beams with different colors is stacked. The light-emitting layer 122 may further include organic material layers such as a hole injection layer, a hole transport layer, an electron transport layer, and an electron injection layer. However, the present disclosure is not limited thereto.

The cathode 123 is disposed on the light-emitting layer 122. Because the cathode 123 supplies electrons to the light-emitting layer 122, the cathode 123 may be made of an electrically conductive material having a low work function. The cathode 123 may be configured as a single layer over the plurality of subpixels SP. That is, the cathodes 123 of the plurality of subpixels SP may be connected to and integrated with one another. However, the present disclosure is not limited thereto.

With reference to FIGS. 6A to 6C, the connection electrode CE is disposed on the planarization layer 114. The connection electrode CE may be disposed on the transistor T and configured to electrically connect the transistor T, the first anode 621a, the second anode 621b, and the third anode 621c. For example, the connection electrode CE may be electrically connected to the source electrode SE of the transistor T, the connection line CL, the first anode 621a, the second anode 621b, and the third anode 621c. However, the present disclosure is not limited thereto.

The connection line CL is disposed on the connection electrode CE, the first anode 621a, the second anode 621b, and the third anode 621c. The connection line CL may be configured to adjoin the transistor T and the plurality of light-emitting elements 620a, 620b, and 620c.

With reference to FIGS. 6A to 6C, the connection line CL includes the first portion CL1, the second portion CL2, and the third portion CL3.

The first portion CL1 is a portion that adjoins the connection electrode CE, extends between the first light-emitting element 620a and the second light-emitting element 620b, and is disposed on a third anode 621c. The second portion CL2 is a portion that extends from the first portion CL1 and covers the end of the first anode 621a of the first light-emitting element 620a. The third portion CL3 is a portion that extends from the first portion CL1 and covers the end of the second anode 621b of the second light-emitting element 620b.

Meanwhile, FIGS. 6A to 6C illustrate a normal subpixel SP that does not have a defect and is not subjected to the repair process. In this case, in case that all the plurality of light-emitting elements disposed in the subpixel SP are normal, the repair process is not performed on the connection line CL disposed in the subpixel SP, and the entire connection line CL may be conductive.

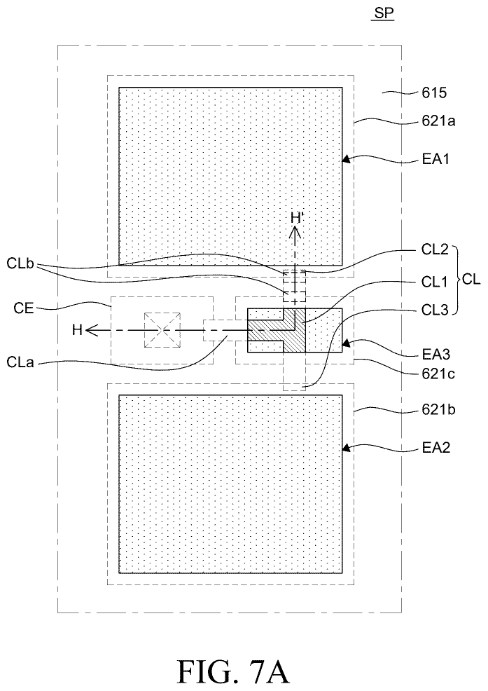

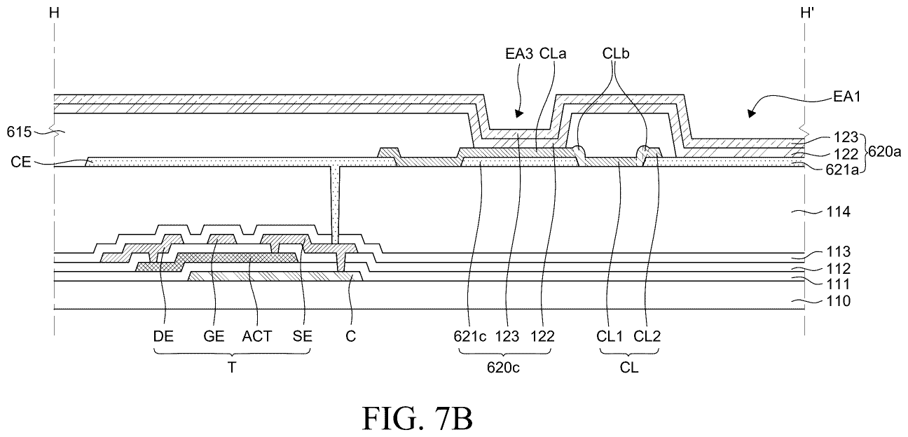

Hereinafter, a method of repairing a subpixel in which a defective light-emitting element is disposed in the display device according to another embodiment of the present disclosure will be described in detail with reference to FIGS. 7A to 10B.

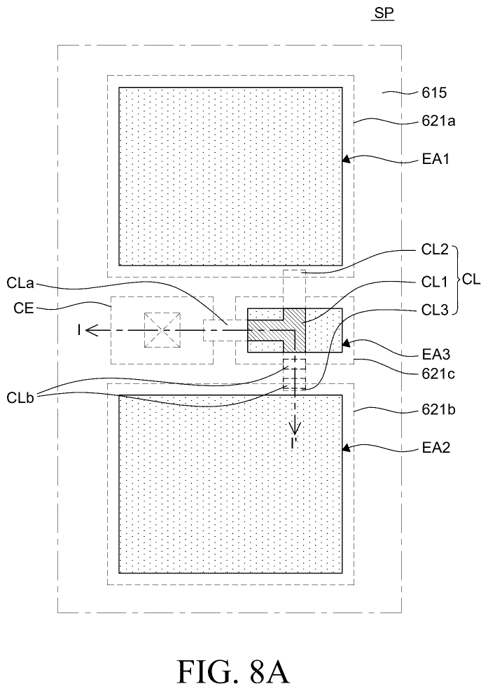

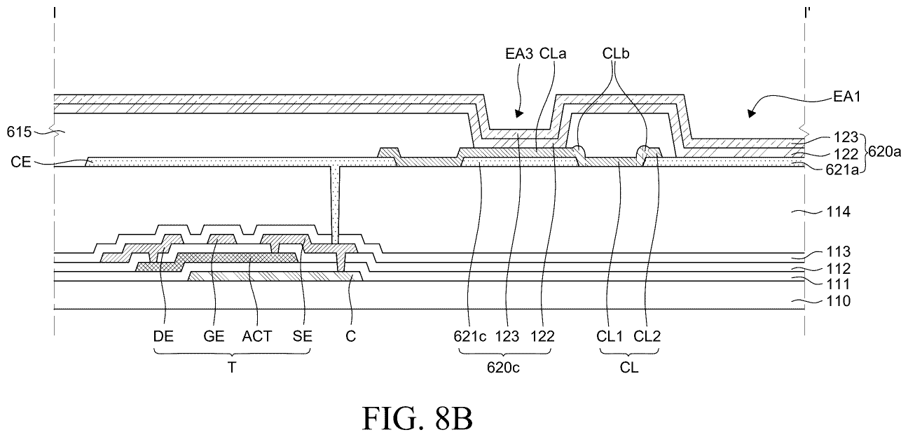

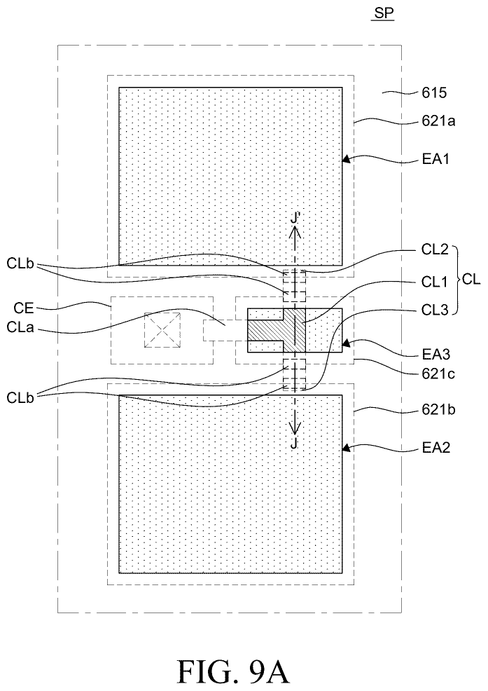

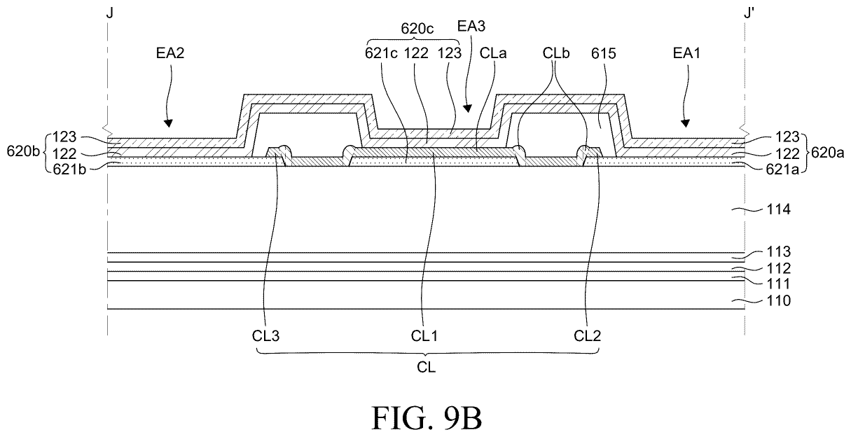

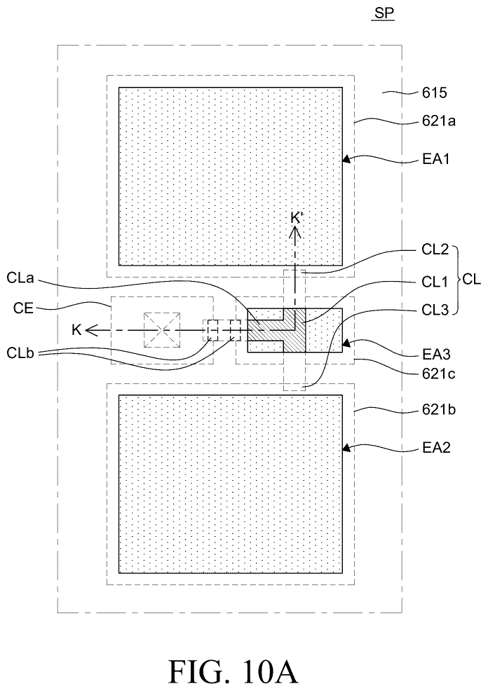

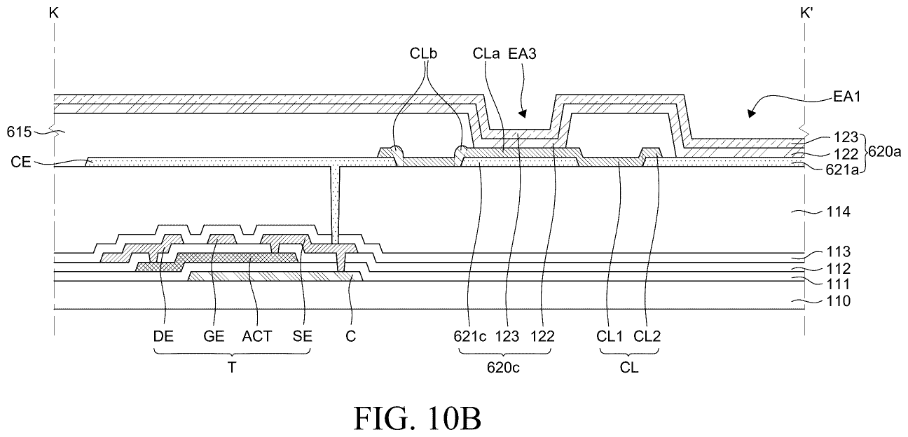

FIG. 7A is an enlarged top plan view of a subpixel in which a first light-emitting element is defective in the display device according to another embodiment of the present disclosure. FIG. 7B is a cross-sectional view taken along line H-H′ in FIG. 7A. FIG. 8A is an enlarged top plan view of a subpixel in which a second light-emitting element is defective in the display device according to another embodiment of the present disclosure. FIG. 8B is a cross-sectional view taken along line I-I′ in FIG. 8A. FIG. 9A is an enlarged top plan view of a subpixel in which a first light-emitting element and a second light-emitting element are defective in the display device according to another embodiment of the present disclosure. FIG. 9B is a cross-sectional view taken along line J-J′ in FIG. 9A. FIG. 10A is an enlarged top plan view of a subpixel in which all a first light-emitting element, a second light-emitting element, and a third light-emitting element are defective in the display device according to another embodiment of the present disclosure. FIG. 10B is a cross-sectional view taken along line K-K′ in FIG. 10A. The display device 600 in FIGS. 7A to 10B is substantially identical in configuration to the display device 100 in FIGS. 1 to 5B, except that the third light-emitting element 620c is further disposed in each of the subpixels SP. Therefore, repeated descriptions of the identical components will be omitted.

With reference to FIGS. 7A to 10B, in the display device 600 according to another embodiment of the present disclosure, the connection line CL of the subpixel SP, which has a bright spot defect or a dark spot defect, includes the low-resistance portion CLa and the high-resistance portion CLb.

First, with reference to FIGS. 7A and 7B, in case that a bright spot defect or a dark spot defect occurs on the first light-emitting element 620a, at least one of the second portion CL2 of the connection line CL, which adjoins the end of the first anode 621a, and the first portion CL1 of the connection line CL, which is opposite to the second portion CL2 and adjoins the end of the third anode 621c, is irradiated with laser beams. Further, the distances between the indium (In) particles included in the connection line CL are increased by the laser irradiation, and the movement of electric current decreases, such that the high-resistance portion CLb, which is a portion with an increased resistance value, is formed. Therefore, because the first light-emitting element 620a, which has a defect, is electrically disconnected from the transistor T by the high-resistance portion, the defect occurring on the first light-emitting element 620a in the subpixel SP may not be visually recognized, and the subpixel SP may be repaired.

Next, with reference to FIGS. 8A and 8B, in case that a bright spot defect or a dark spot defect occurs on the second light-emitting element 620b, at least one of the third portion CL3 of the connection line CL, which adjoins the end of the second anode 621b, and the first portion CL1 of the connection line CL, which is opposite to the third portion CL3 and adjoins the end of the third anode 621c, is irradiated with laser beams. Further, the distances between the indium (In) particles included in the connection line CL are increased by the laser irradiation, and the movement of electric current decreases, such that the high-resistance portion CLb, which is a portion with an increased resistance value, is formed. Therefore, because the second light-emitting element 620b, which has a defect, is electrically disconnected from the transistor T by the high-resistance portion CLb, the defect occurring on the second light-emitting element 620b in the subpixel SP may not be visually recognized, and the subpixel SP may be repaired.

Next, with reference to FIGS. 9A and 9B, in case that a bright spot defect or a dark spot defect occurs on the first light-emitting element 620a and the second light-emitting element 620b, at least one of the second portion CL2 of the connection line CL, which adjoins the end of the first anode 621a, and the first portion CL1 of the connection line CL, which is opposite to the second portion CL2 and adjoins the end of the third anode 621c, and at least one of the third portion CL3 of the connection line CL, which adjoins the end of the second anode 621b, and the first portion CL1 of the connection line CL, which is opposite to the third portion CL3 and adjoins the end of the third anode 621c, are irradiated with laser beams. Further, the distances between the indium (In) particles included in the connection line CL are increased by the laser irradiation, and the movement of electric current decreases, such that the high-resistance portion CLb, which is a portion with an increased resistance value, is formed. Therefore, because the first light-emitting element 620a and the second light-emitting element 620b, which have defects, are electrically disconnected from the transistor T by the high-resistance portion CLb, the defects occurring on the first light-emitting element 620a and the second light-emitting element 620b in the subpixel SP may not be visually recognized, and the subpixel SP may be repaired.

Lastly, with reference to FIGS. 10A and 10B, in case that a bright spot defect or a dark spot defect occurs on all the first light-emitting element 620a, the second light-emitting element 620b, and the third light-emitting element 620c, at least one of the first portion CL1 of the connection line CL, which adjoins the end of the connection electrode CE, and the first portion CL1 of the connection line CL, which is opposite to the first portion CL1 and adjoins the end of the third anode 621c, is irradiated with laser beams. Further, the distances between the indium (In) particles included in the connection line CL are increased by the laser irradiation, and the movement of electric current decreases, such that the high-resistance portion CLb, which is a portion with an increased resistance value, is formed. Therefore, because the first light-emitting element 620a, the second light-emitting element 620b, and the third light-emitting element 620c, which have defects, are electrically disconnected from the transistor T by the high-resistance portion CLb, the defects occurring on the first light-emitting element 620a, the second light-emitting element 620b, and the third light-emitting element 620c in the subpixel SP may not be visually recognized, and the subpixel SP may be repaired.

In the display device 600 according to another embodiment of the present disclosure, the connection line CL is disposed to connect the connection electrode CE, the first anode 621a, the second anode 621b, and the third anode 621c, and the high-resistance portion CLb is disposed on the connection line CL of the subpixel SP in which a defective light-emitting element is disposed, which may minimize a deterioration in reliability of the display device 600 that occurs during the repair process.

Specifically, in the display device 600 according to another embodiment of the present disclosure, the connection line CL may adjoin the end of the connection electrode CE, the end of the first anode 621a, the end of the second anode 621b, and the third anode 621c and electrically connect the transistor T and the plurality of light-emitting elements 620a, 620b, and 620c. Therefore, the connection line CL may serve as a repair part that repairs the subpixel SP, in which the light-emitting element with a dark spot defect or a bright spot defect is disposed, by selectively blocking the electrical connection between the plurality of light-emitting elements 620a, 620b, and 620c and the transistor T.

Further, in case that at least one of the plurality of light-emitting elements 620a, 620b, and 620c is defective, at least one of the first portion CL1, the second portion CL2, and the third portion CL3 of the connection line CL may include the high-resistance portion CLb. In this case, because the high-resistance portion CLb increases the distances between the indium (In) particles and decreases the movement of electric current, the connection line CL, in which the high-resistance portion CLb is disposed, may be configured to substantially electrically disconnect the plurality of light-emitting elements 620a, 620b, and 620c and the transistor T. That is, the connection line CL of the display device 600 according to another embodiment of the present disclosure may be configured to substantially electrically disconnect the plurality of light-emitting elements 620a, 620b, and 620c and the transistor T even without being physically removed. Therefore, it is possible to minimize the problem of the deformation of the arrangement structure of the surrounding constituent elements that occurs when the connection line CL is physically removed during the repair process of electrically disconnecting the transistor T and the defective light-emitting element. Therefore, in the display device 600 according to the embodiment of the present disclosure, the connection line CL is disposed to connect the connection electrode CE, the first anode 621a, the second anode 621b, and the third anode 621c, and the high-resistance portion CLb is disposed on the connection line CL of the subpixel SP in which a defective light-emitting element is disposed, which may minimize a deterioration in reliability of the display device 600 that occurs during the repair process.

The example embodiments of the present disclosure can also be described as follows:

According to an aspect of the present disclosure, a display device may include: a substrate; a transistor disposed on the substrate; a planarization layer disposed on the transistor; a plurality of light-emitting elements disposed on the planarization layer and in the same subpixel; and a connection line configured to adjoin the transistor and the plurality of light-emitting elements, in which the connection line covers an end of an anode of each of the plurality of light-emitting elements, and is made of transparent conductive oxide.

The plurality of light-emitting elements may comprise a first light-emitting element and a second light-emitting element, and the connection line may be disposed between the first light-emitting element and the second light-emitting element, and cover the end of the anode of the first light-emitting element and the end of the anode of the second light-emitting element.

The display device may further comprise a connection electrode disposed on the transistor and electrically connected to the transistor and the connection line.

The connection electrode may be disposed on the same layer as the anodes of the plurality of light-emitting elements.

The connection line, the connection electrode and the anodes of the plurality of light-emitting elements may be disposed on the planarization layer.

The connection line may cover an end of the connection electrode.

The connection line may comprise a first portion configured to adjoin the connection electrode and extending between the first light-emitting element and the second light-emitting element, a second portion extending from the first portion and configured to cover the end of the anode of the first light-emitting element, and a third portion extending from the first portion and configured to cover the end of the anode of the second light-emitting element.

The entire connection line may be conductive.

A thickness of a portion of the connection line, which adjoins an end of the connection electrode, a thickness of a portion of the connection line, which adjoins the end of the anode of the first light-emitting element, and a thickness of a portion of the connection line, which adjoins the end of the anode of the second light-emitting element, may be equal to or smaller than a thickness of the remaining portion.

At least one of the first portion, the second portion, and the third portion may comprise a low-resistance portion, and a high-resistance portion having higher resistance than the low-resistance portion.

At least one of the first light-emitting element and the second light-emitting element may be electrically disconnected from the transistor by the high-resistance portion.

A thickness of the high-resistance portion may be larger than a thickness of the low-resistance portion.

The high-resistance portion of the first portion may adjoin an end of the connection electrode.

The high-resistance portion of the second portion may adjoin the end of the anode of the first light-emitting element, and the high-resistance portion of the third portion may adjoin the end of the anode of the second light-emitting element.

The connection line may include indium, and an indium density of the low-resistance portion may be higher than an indium density of the high-resistance portion.

The plurality of light-emitting elements may further comprise a third light-emitting element disposed between the first light-emitting element and the second light-emitting element.

The connection line may comprise a first portion configured to adjoin the connection electrode, extending between the first light-emitting element and the second light-emitting element, and disposed on an anode of the third light-emitting element; a second portion extending from the first portion and configured to cover the end of the anode of the first light-emitting element; and a third portion extending from the first portion and configured to cover the end of the anode of the second light-emitting element.

The entire connection line may be conductive.

A thickness of a portion of the connection line, which adjoins an end of the connection electrode, a thickness of a portion of the connection line, which adjoins the end of the anode of the first light-emitting element, a thickness of a portion of the connection line, which adjoins the end of the anode of the second light-emitting element, and a thickness of a portion of the connection line, which adjoins an end of an anode of the third light-emitting element, may be equal to or smaller than a thickness of the remaining portion.

At least one of the first portion, the second portion, and the third portion may comprise a low-resistance portion, and a high-resistance portion having higher resistance than the low-resistance portion.

At least one of the first light-emitting element, the second light-emitting element and the third light-emitting element may be electrically disconnected from the transistor by the high-resistance portion.

A thickness of the high-resistance portion may be larger than a thickness of the low-resistance portion.

The high-resistance portion of the first portion may adjoin at least one of an end of the connection electrode and an end of an node of the third light-emitting element.

The high-resistance portion of the second portion may adjoin the end of the anode of the first light-emitting element, and the high-resistance portion of the third portion may adjoin the end of the anode of the second light-emitting element.

The connection line may include indium, and an indium density of the low-resistance portion may be higher than an indium density of the high-resistance portion.

The high-resistance portion may be formed by irradiating the connection line with a laser beam.

According to another aspect of the present disclosure, a display device may include: a substrate on which a plurality of subpixels is disposed; a transistor disposed in each of the plurality of subpixels on the substrate; a first light-emitting element and a second light-emitting element disposed in one subpixel and electrically connected to the same transistor; and a connection line configured to electrically connect the transistor, the first light-emitting element, and the second light-emitting element, in which the connection line is disposed between the first light-emitting element and the second light-emitting element disposed in the one subpixel, configured to cover an end of an anode of each of the first light-emitting element and the second light-emitting element, and made of transparent conductive oxide.

The display device may further comprise a connection electrode disposed on the transistor and electrically connected to the transistor and the connection line.

The connection line may comprise a first portion configured to adjoin the connection electrode and extending between the first light-emitting element and the second light-emitting element; a second portion extending from the first portion and configured to cover the end of the anode of the first light-emitting element; and a third portion extending from the first portion and configured to cover the end of the anode of the second light-emitting element.

When both the first light-emitting element and the second light-emitting element are normal, a thickness of a portion of the connection line, which adjoins an end of the connection electrode, a thickness of a portion of the connection line, which adjoins the end of the anode of the first light-emitting element, and a thickness of a portion of the connection line, which adjoins the end of the anode of the second light-emitting element, may be equal to or smaller than a thickness of the remaining portion.

When at least one of the first light-emitting element and the second light-emitting element is defective, at least one of the first portion, the second portion, and the third portion may comprise a low-resistance portion, and a high-resistance portion having higher resistance than the low-resistance portion.

A thickness of the high-resistance portion may be larger than a thickness of the low-resistance portion.

The connection line may include indium, and an indium density of the low-resistance portion may be higher than an indium density of the high-resistance portion.

The high-resistance portion may be formed by irradiating the connection line with a laser beam.

The display device may further comprise a third light-emitting element disposed between the first light-emitting element and the second light-emitting element.

The connection line may comprise a first portion configured to adjoin the connection electrode, extending between the first light-emitting element and the second light-emitting element, and disposed on an anode of the third light-emitting element; a second portion extending from the first portion and configured to cover the end of the anode of the first light-emitting element; and a third portion extending from the first portion and configured to cover the end of the anode of the second light-emitting element.

It will be apparent to those skilled in the art that the present disclosure is not limited by the above-described example embodiments and the accompanying drawings, and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. The protective scope of the present disclosure should be construed based on the following claims and their equivalents, and it is intended that the present disclosure cover all modifications and variations of this disclosure that come within the scope of the claims and their equivalents.

What is claimed is:

1. A display device, comprising:
a substrate;
a transistor on the substrate;
a planarization layer on the transistor;
a plurality of light-emitting elements on the planarization layer and in a same subpixel; and
a connection line configured to adjoin the transistor and the plurality of light-emitting elements,
wherein the connection line covers an end of an anode of each of the plurality of light-emitting elements and is made of transparent conductive oxide.

2. The display device of claim 1, wherein:
the plurality of light-emitting elements comprises a first light-emitting element and a second light-emitting element; and
the connection line is disposed between the first light-emitting element and the second light-emitting element, and covers the end of the anode of the first light-emitting element and the end of the anode of the second light-emitting element.

3. The display device of claim 2, further comprising:
a connection electrode disposed on the transistor and electrically connected to the transistor and the connection line.

4. The display device of claim 3, wherein the connection electrode is disposed on a same layer as the anodes of the plurality of light-emitting elements.

5. The display device of claim 4, wherein the connection line, the connection electrode, and the anodes of the plurality of light-emitting elements are disposed on the planarization layer.

6. The display device of claim 3, wherein the connection line covers an end of the connection electrode.

7. The display device of claim 3, wherein the connection line comprises:
a first portion configured to adjoin the connection electrode and extending between the first light-emitting element and the second light-emitting element;
a second portion extending from the first portion and configured to cover the end of the anode of the first light-emitting element; and
a third portion extending from the first portion and configured to cover the end of the anode of the second light-emitting element.

8. The display device of claim 7, wherein the entire connection line is conductive.

9. The display device of claim 8, wherein a thickness of a portion of the connection line adjoining an end of the connection electrode, a thickness of a portion of the connection line adjoining the end of the anode of the first light-emitting element, and a thickness of a portion of the connection line adjoining the end of the anode of the second light-emitting element are equal to or smaller than a thickness of the remaining portion of the connection line.

10. The display device of claim 7, wherein at least one of the first portion, the second portion, and the third portion comprises:
a low-resistance portion; and
a high-resistance portion having higher resistance than the low-resistance portion.

11. The display device of claim 10, wherein at least one of the first light-emitting element and the second light-emitting element is electrically disconnected from the transistor by the high-resistance portion.

12. The display device of claim 10, wherein a thickness of the high-resistance portion is larger than a thickness of the low-resistance portion.

13. The display device of claim 10, wherein the high-resistance portion of the first portion adjoins an end of the connection electrode.

14. The display device of claim 10, wherein:
the high-resistance portion of the second portion adjoins the end of the anode of the first light-emitting element; and
the high-resistance portion of the third portion adjoins the end of the anode of the second light-emitting element.

15. The display device of claim 10, wherein:
the connection line includes indium; and
an indium density of the low-resistance portion is higher than an indium density of the high-resistance portion.

16. The display device of claim 3, wherein:
the plurality of light-emitting elements further comprise a third light-emitting element disposed between the first light-emitting element and the second light-emitting element; and
the connection line comprises:
a first portion configured to adjoin the connection electrode, extending between the first light-emitting element and the second light-emitting element, and disposed on an anode of the third light-emitting element;
a second portion extending from the first portion and configured to cover the end of the anode of the first light-emitting element; and
a third portion extending from the first portion and configured to cover the end of the anode of the second light-emitting element.

17. The display device of claim 16, wherein the entire connection line is conductive.

18. The display device of claim 17, wherein a thickness of a portion of the connection line adjoining an end of the connection electrode, a thickness of a portion of the connection line adjoining the end of the anode of the first light-emitting element, a thickness of a portion of the connection line adjoining the end of the anode of the second light-emitting element, and a thickness of a portion of the connection line adjoining an end of an anode of the third light-emitting element are equal to or smaller than a thickness of the remaining portion of the connection line.

19. The display device of claim 16, wherein at least one of the first portion, the second portion, and the third portion comprises:
a low-resistance portion; and
a high-resistance portion having higher resistance than the low-resistance portion.

20. The display device of claim 19, wherein at least one of the first light-emitting element, the second light-emitting element, and the third light-emitting element is electrically disconnected from the transistor by the high-resistance portion.

21. The display device of claim 19, wherein a thickness of the high-resistance portion is larger than a thickness of the low-resistance portion.

22. The display device of claim 19, wherein the high-resistance portion of the first portion adjoins at least one an end of the connection electrode and an end of an anode of the third light-emitting element.

23. The display device of claim 19, wherein:
the high-resistance portion of the second portion adjoins the end of the anode of the first light-emitting element; and
the high-resistance portion of the third portion adjoins the end of the anode of the second light-emitting element.

24. The display device of claim 19, wherein:
the connection line includes indium; and
an indium density of the low-resistance portion is higher than an indium density of the high-resistance portion.

25. The display device of claim 10, wherein the high-resistance portion is formed by irradiating the connection line with a laser beam.

26. A display device, comprising:
a substrate on which a plurality of subpixels are disposed;
a transistor disposed in each of the plurality of subpixels on the substrate;
a first light-emitting element and a second light-emitting element disposed in one subpixel, among the plurality of subpixels, and electrically connected to the same transistor; and
a connection line configured to electrically connect the transistor, the first light-emitting element, and the second light-emitting element,
wherein the connection line is disposed between the first light-emitting element and the second light-emitting element disposed in the one subpixel, is configured to cover an end of an anode of each of first light-emitting element and the second light-emitting element, and is made of transparent conductive oxide.

27. The display device of claim 26, further comprising:
a connection electrode disposed on the transistor and electrically connected to the transistor and the connection line.

28. The display device of claim 27, wherein the connection line comprises:
a first portion configured to adjoin the connection electrode and extending between the first light-emitting element and the second light-emitting element;
a second portion extending from the first portion and configured to cover the end of the anode of the first light-emitting element; and
a third portion extending from the first portion and configured to cover the end of the anode of the second light-emitting element.

29. The display device of claim 28, wherein when both the first light-emitting element and the second light-emitting element are normal, a thickness of a portion of the connection line adjoining an end of the connection electrode, a thickness of a portion of the connection line adjoining the end of the anode of the first light-emitting element, and a thickness of a portion of the connection line adjoining the end of the anode of the second light-emitting element are equal to or smaller than a thickness of the remaining portion of the connection line.

30. The display device of claim 28, wherein when at least one of the first light-emitting element and the second light-emitting element is defective, at least one of the first portion, the second portion, and the third portion comprises:
a low-resistance portion; and
a high-resistance portion having higher resistance than the low-resistance portion.

31. The display device of claim 30, wherein a thickness of the high-resistance portion is larger than a thickness of the low-resistance portion.

32. The display device of claim 30, wherein:
the connection line includes indium; and
an indium density of the low-resistance portion is higher than an indium density of the high-resistance portion.

33. The display device of claim 30, wherein the high-resistance portion is formed by irradiating the connection line with a laser beam.

34. The display device of claim 27, further comprising a third light-emitting element disposed between the first light-emitting element and the second light-emitting element,
wherein the connection line comprises:
a first portion configured to adjoin the connection electrode, extending between the first light-emitting element and the second light-emitting element, and disposed on an anode of the third light-emitting element;
a second portion extending from the first portion and configured to cover the end of the anode of the first light-emitting element; and
a third portion extending from the first portion and configured to cover the end of the anode of the second light-emitting element.
